(19) United States
(12) Patent Application Publication
(10) Pub. No.: US 2025/0099950 A1
(43) Pub. Date: Mar. 27, 2025

(54) INTEGRATED CENTRALIZED VACUUM INTERCONNECTION SYSTEM DEVICE

(71) Applicant: UNIVERSITY OF SCIENCE AND TECHNOLOGY OF CHINA, Hefei City (CN)

(72) Inventors: Hui ZHANG, Hefei City (CN); Jinze FAN, Hefei City (CN)

(73) Assignee: UNIVERSITY OF SCIENCE AND TECHNOLOGY OF CHINA, Hefei City (CN)

(21) Appl. No.: 18/619,171

(22) Filed: Mar. 28, 2024

(30) Foreign Application Priority Data
Sep. 27, 2023 (CN) 2023112590085

(51) Int. Cl. B01L 1/02

(52) U.S. Cl. CPC B01L 1/025; B01L 2200/026; B01L 2300/0645; B01L 2300/1827; B01L 2400/049

(57) ABSTRACT

An integrated centralized vacuum interconnection system device is provided, which belongs to the field of vacuum interconnection technology. The device includes an interconnection tower, the top of the interconnected tower is connected with an evaporation pattern direct writing device, the interconnected tower is connected with a combined modular measuring device on the adjacent side below the evaporation pattern direct writing device, the middle of the interconnected tower is connected with a fast extension module device and a fast separation damping device respectively, a side of the middle part of the interconnected tower and the lower part of the middle part of the interconnected tower are equipped with a combined modular evaporation device. The present invention provides an integrated centralized vacuum interconnection system device that integrates sample preparation, sample characterization, device fabrication, and comprehensive measurement components. The central functions of each component are executed on a replaceable universal module.

### TECHNICAL FIELD

The invention relates to the field of vacuum interconnection technology, in particular to an integrated centralized vacuum interconnection system device.

### BACKGROUND ART

In recent years, vacuum interconnection system devices have been increasingly used in the field of preparation and property research of new materials. The current vacuum interconnection device primarily connects the sample preparation device and the sample characterization device through the vacuum transmission tube and control system, which provides a clean environment without water and oxygen for the preparation and transmission of materials. The materials that can be prepared in vacuum interconnection devices mainly include: III-VA semiconductors, transition metal dichalcogenides, topological insulators, superconductors and magnetic materials, etc. The following are preparation techniques for these materials: (1) Molecular beam epitaxy (MBE); (2) Magnetron sputtering; (3) Laser-assisted pulse deposition; (4) Chemical vapor deposition; (5) Atomic layer deposition, etc. In addition to material growth, the characterization of material properties is also an extremely important part, wherein the main methods are as follows: Scanning tunneling microscope (STM), Atomic force microscope, Angle-resolved photoelectron spectroscopy (ARPES), etc.; these measuring instruments have the following characteristics: (1) they have high real space resolution or momentum space resolution; (2) they are extremely sensitive to the surface quality of the sample, requiring high flatness and high purity, so they are particularly dependent on the vacuum interconnection device. To realize practical applications, the preparation of functional electronic device is also an important content, at present, the most commonly used devices are: (1) electrode deposition device, including Magnetron sputtering device, Thermal evaporation device and Electron beam evaporation device, etc.; (2) Ion beam etching device and Reactive ion beam etching device; (3) Spin-coating device, UV lithography device and Electron beam lithography device.

In the future, vacuum interconnection device is expected to progress in the following directions: (1) standardization, automation and intelligentization: a big problem caused by the interconnection device is the large number of equipment, and the fact that most equipment is not purchased from the same manufacturer, the standard is not uniform. Meanwhile, complex operations will bring great burden to operators and increase training and maintenance costs. Therefore, standardization, automation and intelligentization have become an urgent need for future interconnection devices; (2) portability and simplification: due to the complexity of the vacuum interconnection device, the large number of instruments and equipment they require, it is difficult to achieve effective control in certain special occasions. Therefore, it is necessary to simplify the original design to obtain an optimal layout scheme; (3) integration: in the traditional interconnection device, the sample needs to go through different vacuum purity when being transmitted between various chambers, which poses a risk of contamination. In addition, the more complex the transmission process is, the higher the experimenter's error rate increase, every minor error leads to a waste of time and effort. Therefore, it is necessary to optimize the structure of the vacuum interconnection device, and closely integrate the growth equipment with the measurement equipment to streamline the transport process; (4) modularization: at present, the vacuum interconnection device exhibits weak scalability, requiring a disruption of the ultra-high vacuum environment during maintenance or replacement of equipment within the vacuum chamber. In particular, the Molecular beam epitaxy device needs to be bled each time the raw materials run out or different materials are introduced, and the subsequent assembly and baking steps usually cause several days' delay to the experiment. If the modular design is adopted, the disassembly of the vacuum interconnection device can be avoided, which greatly enhances flexibility and scalability.

### SUMMARY

The purpose of the present invention is to provide an integrated centralized vacuum interconnection system device, which solves the issues of limited integration, large coverage area, absence of modular design, and lack of scalability in the current vacuum interconnection system.

In order to achieve the above purpose, the present invention provides an integrated centralized vacuum interconnection system device, including an interconnection tower, the top of the interconnected tower is connected with an evaporation pattern direct writing device, the interconnected tower is connected with a combined modular measuring device on the adjacent side below the evaporation pattern direct writing device, the middle of the interconnected tower is connected with a fast extension module device and a fast separation damping device respectively, a side of the middle part of the interconnected tower and the lower part of the middle part of the interconnected tower are equipped with a combined modular evaporation device;

the combined modular evaporation device includes an evaporation main body, the bottom of the evaporation main body is connected with a cooling water pipe, outer side of the evaporation main body is connected with a cooling shield cover, the upper surface of the evaporation main body is equipped with an evaporation bearing device installation table, an combined control baffle is arranged above the evaporation bearing device installation table, the combined control baffle is connected with the evaporation main body through a reversing rotation device, the evaporation bearing device installation table is connected with a thermal evaporation bearing device and an electron beam evaporation bearing device, the inner side of the evaporation bearing device installation table is provided with a contact thermocouple device, and a uniformly arranged access electrode is arranged above the contact thermocouple device;

the combined modular measuring device includes a probe displacement table, a probe device slot is arranged above the probe displacement table, the probe device slot is connected with the probe device, a uniformly arranged elastic electrode is arranged in the center of the probe device slot, a sample holder slot is arranged above the probe device slot, a heating rod is arranged above the sample holder slot, and a low temperature measuring thermocouple is set on one side of the heating rod;

the fast extension module device includes a movable bracket, a fast connection base is arranged below the movable bracket, wire routing holes are set inside the movable bracket, and two carrying handles are set in the center above the movable bracket;

the evaporation pattern direct writing device includes a precision two-dimensional translation table, a collimating pipe with an evaporation bearing device slot is arranged at the center of the precise two-dimensional translation table, and pattern holes are arranged above the collimating pipe with the evaporation bearing device slot.

Preferably, the thermal evaporation bearing device includes a ceramic crucible, a heating resistance wire is wrapped around the outside of the ceramic crucible, the bottom of the ceramic crucible is connected with a bearing base I, the heating resistance wire is connected with an electrode I, and the electrode I is connected with an insulating ceramic block I arranged on one side of the bearing base I.

Preferably, the electron beam evaporation bearing device includes a metal crucible, a tungsten wire is arranged in the outer center of the metal crucible, the bottom of the metal crucible is connected with the ceramic base set at the center of the bearing base II, the side of the bearing base II is provided with an insulating ceramic block II, an electrode II is arranged on the insulating ceramic block II, the electrode II is connected to a tungsten wire fixation sheet by a connecting wire, the tungsten wire fixation sheet are connected with the tungsten wire, a ceramic gasket is arranged between the tungsten wire fixation sheet and a fixation nut, the metal crucible is connected with high voltage wiring, the high voltage wiring is connected with the metal crucible and the electrode II, and the outer side of the high voltage wiring is provided with a shielding shell.

Preferably, the probe device includes a bearing base III, and the bearing base III is connected with a holed ceramic, and the holed ceramic is connected with an electrode probe.

Therefore, the present invention adopts an integrated centralized vacuum interconnection system device, which has the following beneficial effects:

(1) The present invention adopts the mode of interconnected tower and combines a variety of inventive devices, mainly including: modular evaporation and detection series devices, electrode preparation and property measurement series devices, extension devices, etc. The integrated process from material growth to device testing is realized. Moreover, the interconnected tower can also be connected to additional equipment such as Scanning tunneling microscope, Angle-resolved photoelectron spectroscopy through the fast separation damping device, enabling the establishment of an interconnection network centered around the interconnected tower.

(2) The present invention introduces a modular approach to the entire device, the evaporation source in the molecular beam epitaxy device and the evaporation pattern direct writing device is replaced by a modular thermal evaporation bearing device and an electron beam evaporation bearing device. Modular probe devices is invented to carry a variety of sample performance testing functions. This modular evaporation device and probe device can be easily replaced without disturbing the vacuum, so as to change the evaporation material and growth parameters, change the test function of the measuring equipment, and realize the coverage of all the functions of the original interconnection equipment within a small number of standardized cavities, which not only provides flexibility and convenience but also significantly enhances the overall efficiency of the equipment.

(3) The interconnected tower in the invention combines the evaporation and sample transmission functions, enabling seamless completion of these tasks in a unified and efficient manner. By making full use of vertical space, interconnected tower efficiently reduces the occupied area, making the instrument suitable for use even in constrained laboratory environments. Additionally, the film growth rate and film quality can be precisely controlled by adjusting the distance between the sample and the evaporation source.

(4) The evaporation pattern direct writing device in the invention eliminates the need for masks and instead directly creates the required patterns by moving the evaporation bearing device along with the corresponding micro holes above it, which can greatly broaden the range of the patterns that can be prepared. In addition, by precisely controlling the movement speed and evaporation rate, patterns with different thicknesses can be realized, which further enriches the types of functional patterns and opens up new possibilities for more applications.

(5) The fast extension module in the invention can greatly compress the volume of the evaporation or measurement device, facilitating its transfer from the atmosphere to the inside of a vacuum chamber. Once inside the vacuum chamber, the fast extension module can be expanded to create sufficient space for sample preparation or measurement procedures. Upon completion, the fast expansion module can be contracted and taken out of the vacuum chamber. The device can maximize the use of vacuum equipment, save the cost of vacuum pump bodies and shock absorption supports. It holds great potential in the space station environment, where experiments can be conducted in the vacuum of outer space.

The following is a further detailed description of the technical scheme of the invention through drawings and implementation examples.

### BRIEF DESCRIPTION OF THE DRAWINGS

FIG. 1 is a structural schematic diagram of an integrated centralized vacuum interconnection system device of the present invention;

FIG. 2 is a schematic diagram of an integrated modular evaporation device structure of an integrated centralized vacuum interconnection system device of the present invention;

FIG. 3 is a schematic diagram of the structure of a thermal evaporation bearing device of an integrated centralized vacuum interconnection system device of the present invention;

FIG. 4 is a schematic diagram of the structure of an electron beam evaporation bearing device of an integrated centralized vacuum interconnection system device of the present invention;

FIG. 5 is a schematic diagram of the structure of an integrated modular measuring device of an integrated centralized vacuum interconnection system device of the present invention;

FIG. 6 is a schematic diagram of the probe device structure of an integrated centralized vacuum interconnection system device of the present invention.

FIG. 7 is a schematic diagram of the structure of the fast extension module device of an integrated centralized vacuum interconnection system device of the present invention when it is closed;

FIG. 8 is a schematic diagram of the extension structure of the fast extension module device an integrated centralized vacuum interconnection system device of the present invention when it is extended; and

FIG. 9 is a schematic diagram of the structure of an evaporation pattern direct writing device of an integrated centralized vacuum interconnection system device of the present invention.

### Labels of drawings

1. combined modular evaporation device; 2. combined modular measuring device; 3. interconnection tower; 4. fast extension module device; 5. evaporation pattern direct writing device; 6. fast separation damping device; 11. evaporation main body; 12. cooling water pipe; 13. reversing rotation device; 14. cooling shield cover; 15. evaporation bearing device installation table; 16. contact thermocouple device; 17. access electrode; 18. combined control baffle; 101. ceramic crucible; 102, heating resistance wire; 103. insulating ceramic block I; 104. electrode I; 105, bearing base I; 111. metal crucible; 112. tungsten wire; 113. shielding shell, 114. ceramic gasket; 115. ceramic base, 116. bearing base II; 117. connecting wire, 118, insulating ceramic block II, 119. electrode II; 21. probe displacement table, 22. low temperature measuring thermocouple; 23. heating rod; 24. sample holder slot; 25, probe device slot; 26, elastic electrode; 27. bearing base III; 28. holed ceramic; 29. electrode probe; 210. probe device; 41. movable bracket; 42. wire routing hole; 43. carrying handle; 44. fast connection base; 51. precision two-dimensional translation table; 52. pattern hole; 53. collimated pipe with evaporation bearing device slot.

### DETAILED DESCRIPTION OF THE EMBODIMENTS

The technical scheme of the invention is further explained below by drawings and embodiments.

Unless otherwise defined, the technical terms or scientific terms used in the invention shall be understood by persons with general skills in the field to which the invention belongs. The words ‘first’, ‘second’, and the like used in this invention do not represent any order, quantity, or importance, but are only used to distinguish different components. Similar words such as ‘include’ or ‘comprise’ mean that the elements or objects in front of the word cover the elements or objects listed after the word and their equivalents, without excluding other elements or objects. Similar words such as ‘connect’ or ‘link’ are not limited to physical or mechanical connections, but can include electrical connections, whether direct or indirect. ‘Up’, ‘down’, ‘left’, ‘right’, etc. are only used to represent the relative positional relationship, when the absolute position of the described object changes, the relative positional relationship may also change accordingly.

### Example 1

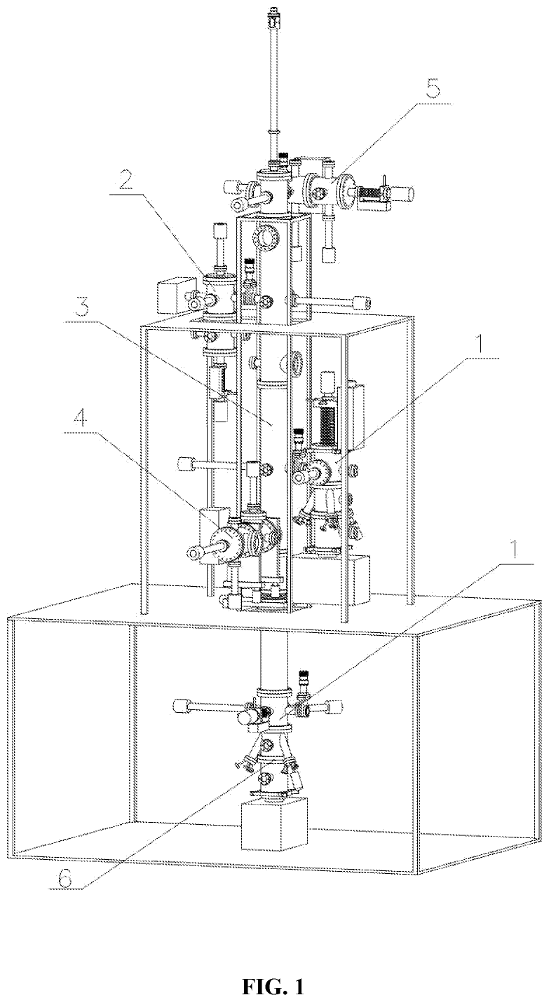

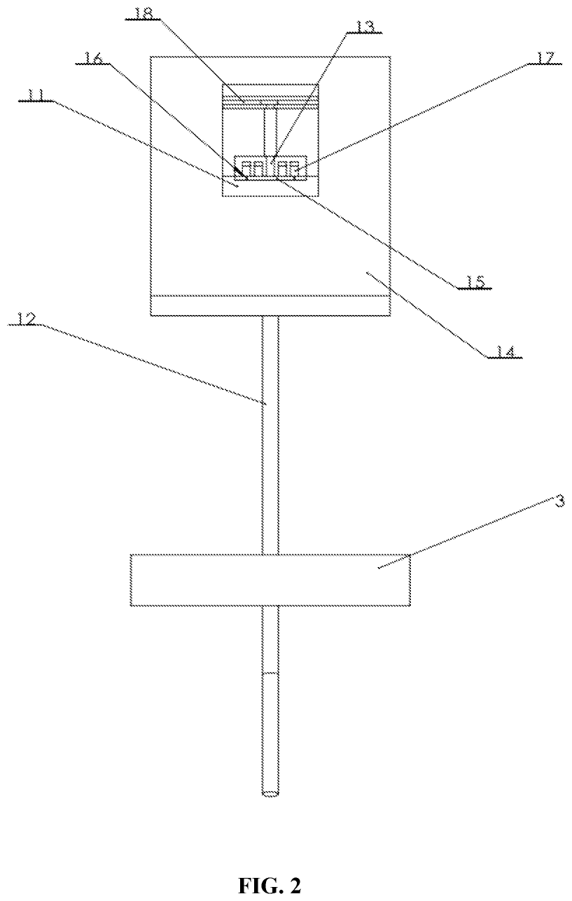

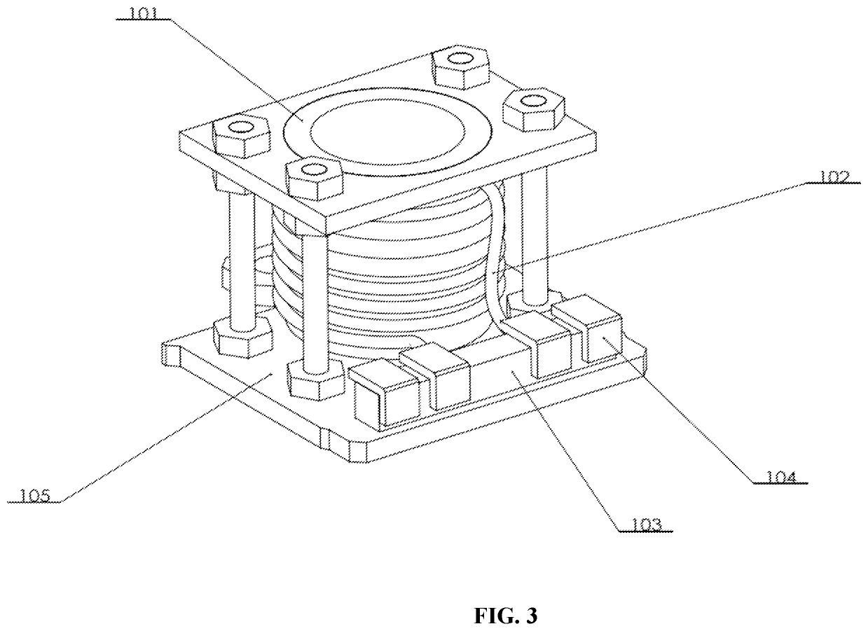

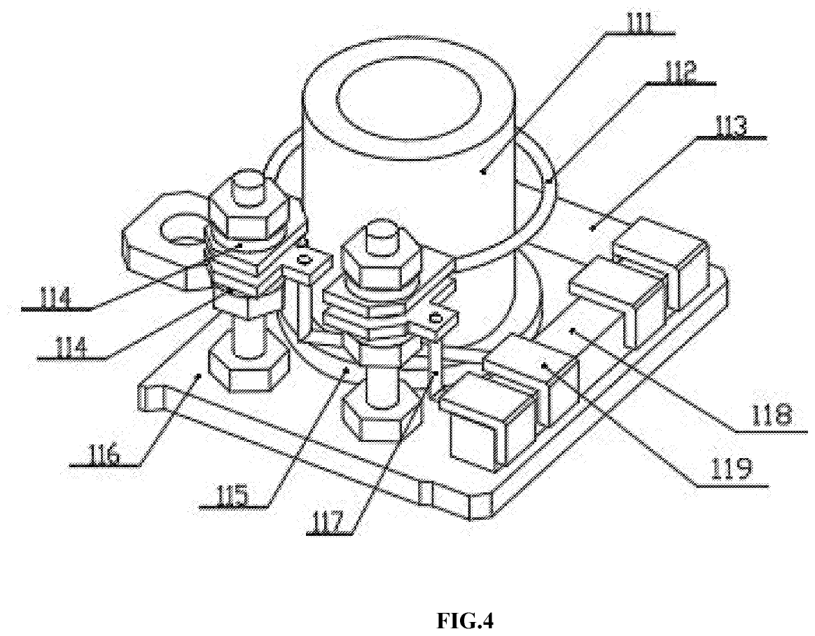

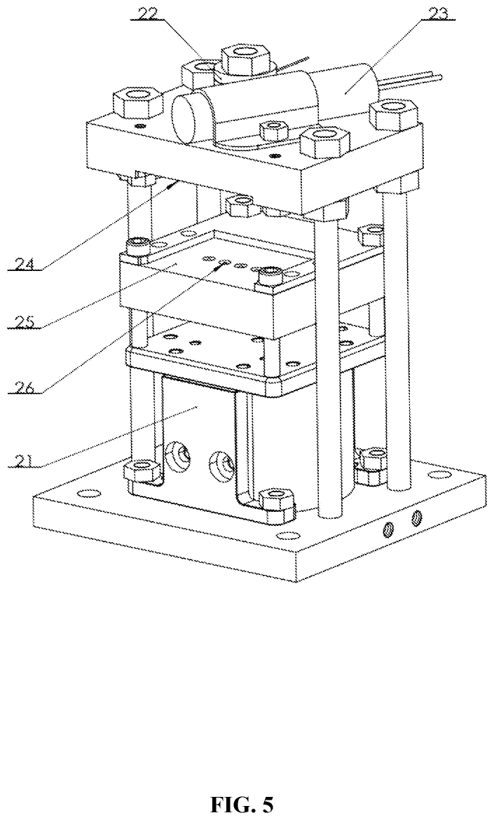

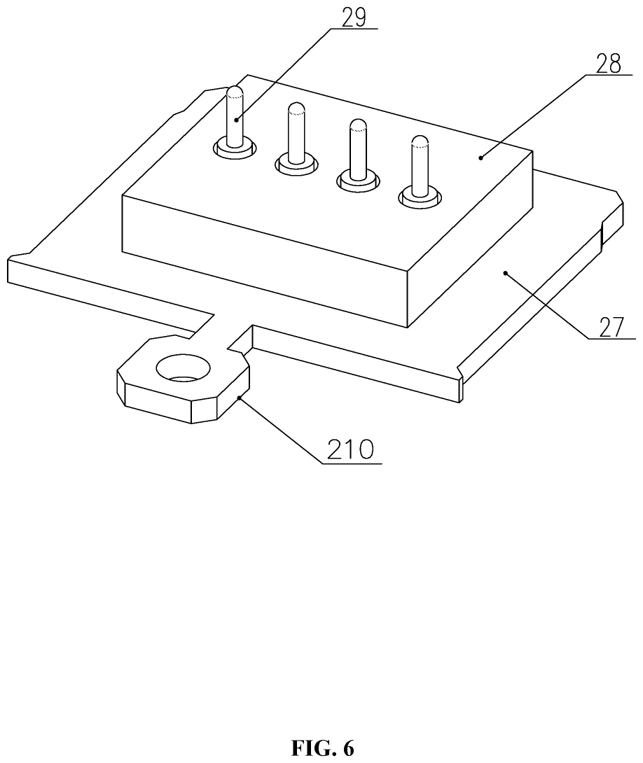

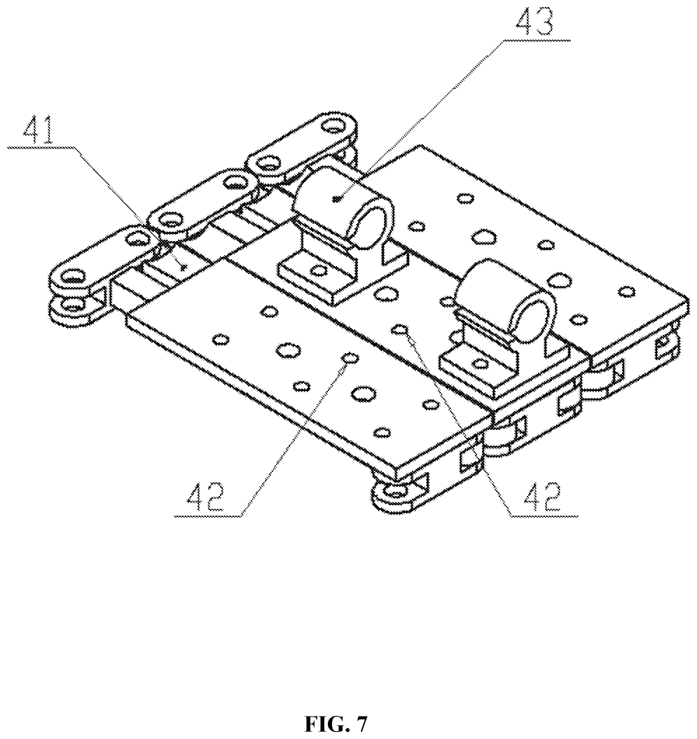

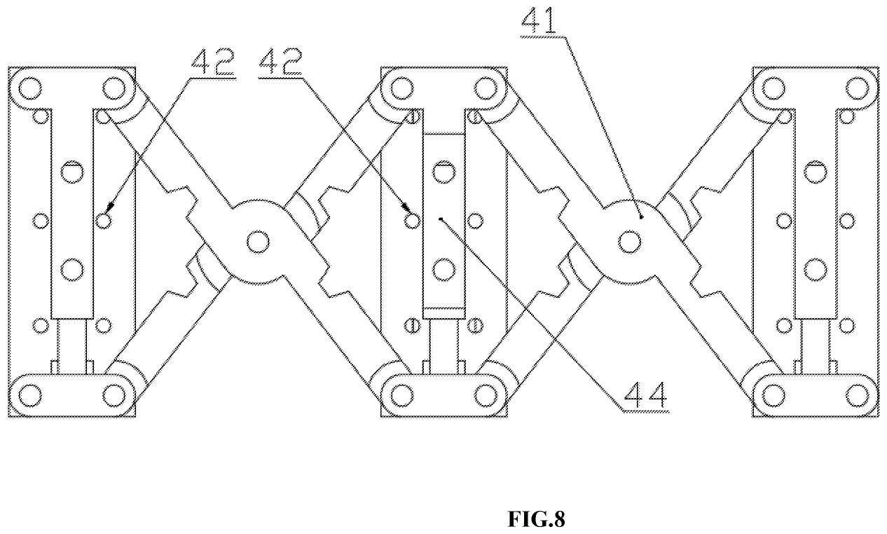

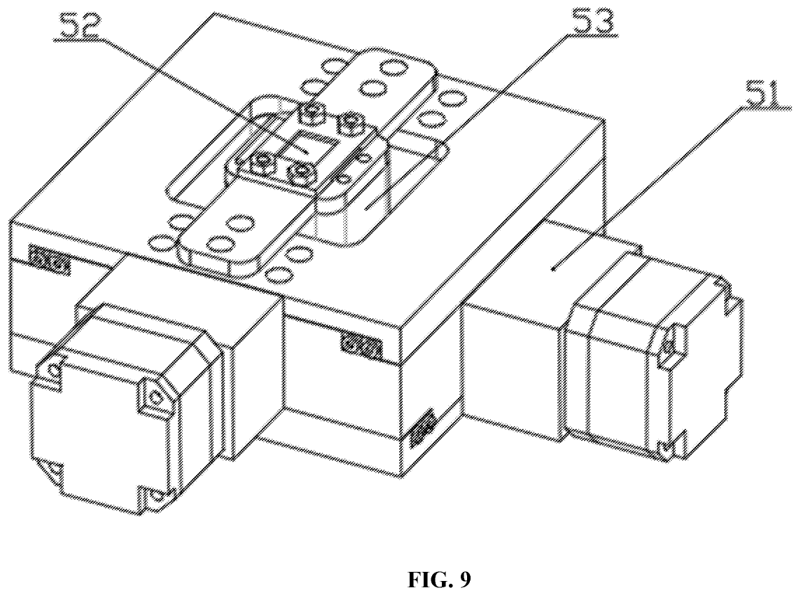

As shown in FIGS. 1-9, the present invention provides an integrated centralized vacuum interconnection system device, including an interconnection tower 3, the top of the interconnected tower 3 is connected with an evaporation pattern direct writing device 5, the interconnected tower 3 is connected with a combined modular measuring device 2 on the adjacent side below the evaporation pattern direct writing device 5, the middle of the interconnected tower 3 is connected with a fast extension module device 4 and a fast separation damping device 6 respectively, a side of the middle part of the interconnected tower 3 and the lower part of the middle part of the interconnected tower 3 are equipped with a combined modular evaporation device 1. The combined modular evaporation device 1 includes an evaporation main body 11, the evaporation main body 11 includes a cooling shield 14 and a cooling water pipe 12, the cooling shield cover 14 is connected with the cooling water pipe 12, the internal top of the cooling shield 14 is provided with an combined control baffle 18 connected with the cooling water pipe 12, the central part of the cooling shield 14 is equipped with an evaporation bearing device installation table 15, the evaporation bearing device installation table 15 is connected with a thermal evaporation bearing device and an electron beam evaporation bearing device, a contact thermocouple device 16 is set on one side of the evaporation bearing device installation table 15, a reversing rotation device 13 is set in the center of the evaporation bearing device installation table 15, both sides of the reversing rotation device 13 are equipped with evenly arranged access electrodes 17. The thermal evaporation bearing device includes a ceramic crucible 101, the outer side of the ceramic crucible 101 is wrapped around a heating resistance wire 102, the lower part of the ceramic crucible 101 is connected to a bearing base I 105, the heating resistance wire 102 is connected to an electrode I 104, and the electrode I 104 is connected to the insulating ceramic block I 103 set on the side of the bearing base I 105. The electron beam evaporation bearing device includes a metal crucible 111, the outer center of the metal crucible 111 is provided with a tungsten wire 112, the lower part of the metal crucible 111 is connected to the ceramic base 115 set at the center of the bearing base II 116, the insulating ceramic block II 118 is set on the side of the bearing base II 116, and the electrode II 119 is set on the insulating ceramic block II 118, the electrode II 119 is connected with a tungsten wire fixation sheet and a connecting wire 117, the tungsten wire fixation sheet and the connecting wire 117 are connected with the tungsten wire 112, a ceramic gasket 114 is arranged between the tungsten wire fixation sheet and the connecting wire 117 and the tungsten wire 112, the bearing base II 116 is connected with high voltage wiring and shielding shell 113. The integrated modular measuring device 2 includes a probe displacement table 21, and the probe displacement table 21 is connected with the probe device 210, a probe device slot 25 is arranged above the probe displacement table 21, and a uniformly arranged elastic electrode 26 is arranged at the center of the probe device slot 25, a sample holder slot 24 is arranged above the probe device slot 25, a heating rod 23 is arranged above the sample holder slot 24, and a low temperature measuring thermocouple 22 is arranged on one side of the heating rod 23. The probe device 210 includes a bearing base III 27, which is connected with a holed ceramic 28 above the bearing base III 27, and the holed ceramic 28 is connected with the electrode probe 29. The fast extension module device 4 includes a fast connection base 44, wire routing holes 42 are arranged above the fast connection base 44, two carrying handles 43 are arranged in the center of the fast connection base 44, and the movable supports 41 are connected on both sides of the fast connection base 44. The evaporation pattern direct writing device 5 includes a precision two-dimensional translation table 51, a collimated pipe with evaporation bearing device slot 53 is set in the center of the precision two-dimensional translation table 51, and graphic holes are arranged above the collimating pipe with the evaporation bearing device slot. The vacuum of the whole device can reach 1×10⁻⁶ mbar ˜1×10⁻¹⁰ mbar.

For the combined modular evaporation device described in the public, its specific implementation can be performed through the following steps:

S11. selecting the appropriate type of a thermal evaporation bearing device or an electron beam evaporation bearing device according to the needs, inserting it into the combined modular evaporation device, an electrode in the evaporation bearing device and an access electrode in the combined modular evaporation device are in contact with each other, closing the cooling shield and moving the substrate to be grown above the integrated modular evaporation device;

S12. the cooling water is introduced into the evaporation main body, and the crucible is heated by resistance wire or tungsten wire, the heating process is controlled and monitored in real time by the contact thermocouple device, after the temperature meets the demand for material growth, the combined control baffle is opened by a reversing rotation device to grow the sample;

S13. during the growth process, the detection equipment is used for in-situ detection, including beam monitoring, film thickness capacitance monitoring, etc.;

S14. the external field is applied to induce the assisted growth process, including electric field input, microwave input, etc.;

S15. after the sample growth is completed, the combined control baffle is closed by the reversing rotation device, and the current is controlled to slowly cool the crucible, and the sample is moved in situ to other cavities through the interconnection tower.

Through the above specific implementation methods, efficient and flexible material preparation can be achieved according to the experimental needs.

### Example 2

(2) For the combined modular measuring device described in the public, its specific implementation can be performed through the following steps:

S21. selecting appropriate type of probe device, inserting the probe device into the probe device slot in the combined modular measuring device;

S22. putting the sample to be measured into the sample holder slot in the measuring device, and using the probe displacement device to accurately adjust the distance between the probe and the sample. If in-situ transport measurement, electrical measurement, and point contact spectrum measurement are performed, the probe needs to directly contact with the sample surface;

S23. the temperature measurement and control devices are used to measure and adjust the temperature of the sample, after the sample temperature reaches the required temperature, the measurement is performed;

S24. magnetic field induction and monitoring devices are used to apply horizontal and vertical magnetic fields on the surface of the sample to obtain the spin flip and Hall effect;

S25. using an optical introduction device to introduce optical information from visible to near-infrared bands on the surface of the sample to stimulate electron-hole pairs and plasmons;

S26. after the experiment, the sample is moved to the next device through the interconnection tower.

Through the above specific implementation methods, the combined modular measuring device can be used to obtain the required experimental results quickly and accurately.

### Example 3

(3) For the combined modular evaporation device located inside the interconnected tower described in the public, the specific implementation method can be performed through the following steps:

S31. checking whether the magnetic damping and anti-collision mechanism at the bottom of the interconnection tower can work normally to avoid the damage caused by the accidental fall of the sample due to various reasons;

S32. according to the need, the appropriate type of thermal evaporation bearing device or electron beam evaporation bearing device is selected and inserted into the combined modular evaporation device, an electrode in the replaceable evaporation bearing device and an access electrode in the combined modular evaporation device are in contact with each other, the cooling shield is closed, and the cooling water is introduced into the evaporation main body;

S33. the sample to be grown is introduced into the interconnection tower and moved to required height on the vertical track through the transmission mechanism;

S34. according to the actual needs, the appropriate growth parameters are set, including the distance between sample and evaporation source, the sample temperature, the temperature of the combined modular evaporation device, etc. The sample is fixed by the locking mechanism, and the combined control baffle is opened by the reversing rotation device to prepare the sample in the tower;

S35. after the sample growth is completed, the combined control baffle is closed by the reversing rotation device, control the current to zero slowly, cool the crucible and move the sample in situ to other chambers.

Through the above specific implementation methods, the combined modular evaporation device inside the interconnected tower can be used to realize the growth preparation and linear transmission of the sample in the vertical direction, so as to make more effective use of space.

### Example 4

(4) For a fast extension module device described in the public, the specific implementation method can be carried out through the following steps:

S41. according to the actual needs, a combined modular evaporation device, a combined modular measurement device, a room temperature scanning tunnel microscopy system or a stress release and measurement system are installed on the fast extension module device;

S42. the import mechanism is used to transmit the fast extension module device to the interior of the chamber, and the fast connection base is connected with the support frame inside the chamber. Wherein, the import mechanism can choose a commercial magnetic sample transfer rod, and lock it with the import handle by rotating the sample transfer rod to ensure safe transmission, it can also be transmitted by clamping, magnet and so on;

S43. the fast extension module device is expanded inside chamber. To promote the deployment, the scheme can choose the above introduction mechanism or additive vacuum motor. Wherein, both schemes can be applied to extension module devices of different sizes and specifications;

S44. the corresponding material preparation and testing work is performed.

Through the above specific implementation method, the fast extension module device can be quickly introduced into the chamber, and the corresponding material preparation and testing work can be performed. Meanwhile, the vacuum of the chamber can be controlled between 1×10⁻⁶ mbar and 1×10⁻¹⁰ mbar, which can meet the needs of the experiment.

### Example 5

(5) For an evaporation pattern direct writing device described in the public, the specific implementation method can be performed through the following steps:

S51. determining the starting position of the sample and the evaporation bearing device. The required electrode pattern and thickness are set in the control system. If there is an oxide layer or impurity on material surface, it can be cleaned by argon ion sputtering;

S52. through the parallelism monitoring and control system, the precise parallelism between the pattern hole and the sample surface is realized, while the capacitance monitoring system is used to measure and maintain the spacing at the micron level;

S53. the evaporation process is started, and the evaporation rate is controlled by the evaporation control system. Meanwhile, the movement of the evaporation bearing device is controlled by the precision displacement table to ensure the quality and accuracy of the pattern;

S54. finally, the on-off of the electrode is detected in situ by fast connection electrode.

Through the above specific implementation methods, the electrode pattern can be completed quickly and efficiently by using the evaporation and etching pattern direct writing device.

### Example 6

(6) For a fast separation damping device described in the public, the interconnection tower can be connected with STM, ARPES and other equipment, taking the separation and connection of STM chamber and interconnection tower as an example, the specific implementation methods are as follows:

S61. the height and position of the docking ring on the fast separation damping device are adjusted, aligned with the bellow on the STM chamber, and accurate alignment is achieved through the external optical guidance device;

S62. connecting the bellow of the STM chamber to the docking ring of the interconnecting tower via the ISO flange buckle;

S63. the long bellows of the fast separation damping device is connected to the molecular pump, and the transition pipe of the rapid separation shock absorption device is pumped to 10-7 mbar through the molecular pump, so that the sample transmission can be performed without affecting sample;

S64. through the damping devices (such as spring chassis, air leg, etc.) installed under the interconnection tower and STM chamber respectively to reduce the vibration and ensure the stability of the instrument;

S65. through the sample transmission mechanism to achieve the transmission of the sample between the interconnection tower and the STM chamber.

Therefore, the invention adopts the above-mentioned fast separation damping device, so that the STM and other equipment can be quickly separated and connected with the interconnection tower, so as to meet the requirements of shielding the vibration when the STM is finely characterized, meanwhile, it can also shorten the time to restore vacuum for sample transmission after the characterization is completed.

Finally, it should be noted that the above implementation examples are only used to explain the technical scheme of the invention rather than to restrict it. Although the invention is described in detail with reference to the better implementation examples, ordinary technicians in this field should understand that they can still modify or replace the technical scheme of the invention, and these modifications or equivalent replacements cannot make the modified technical scheme out of the spirit and scope of the technical scheme of the invention.

What is claimed is:

1. An integrated centralized vacuum interconnection system device, comprising an interconnection tower, the top of the interconnected tower is connected with an evaporation pattern direct writing device, the interconnected tower is connected with a combined modular measuring device on the adjacent side below the evaporation pattern direct writing device, the middle of the interconnected tower is connected with a fast extension module device and a fast separation damping device respectively, a side of the middle part of the interconnected tower and the lower part of the middle part of the interconnected tower are equipped with a combined modular evaporation device;
the combined modular evaporation device comprises an evaporation main body, the bottom of the evaporation main body is connected with a cooling water pipe, outer side of the evaporation main body is connected with a cooling shield cover, the upper surface of the evaporation main body is equipped with an evaporation bearing device installation table, an combined control baffle is arranged above the evaporation bearing device installation table, the combined control baffle is connected with the evaporation main body through a reversing rotation device, the evaporation bearing device installation table is connected with a thermal evaporation bearing device and an electron beam evaporation bearing device, the inner side of the evaporation bearing device installation table is provided with a contact thermocouple device, and a uniformly arranged access electrode is arranged above the contact thermocouple device;
the combined modular measuring device comprises a probe displacement table, a probe device slot is arranged above the probe displacement table, the probe device slot is connected with the probe device, a uniformly arranged elastic electrode is arranged in the center of the probe device slot, a sample holder slot is arranged above the probe device slot, a heating rod is arranged above the sample holder slot, and a low temperature measuring thermocouple is set on one side of the heating rod;
the fast extension module device comprises a movable bracket, a fast connection base is arranged below the movable bracket, wire routing holes are set inside the movable bracket, and two carrying handles are set in the center above the movable bracket;
the evaporation pattern direct writing device comprises a precision two-dimensional translation table, a collimating pipe with an evaporation bearing device slot is arranged at the center of the precise two-dimensional translation table, and pattern holes are arranged above the collimating pipe with the evaporation bearing device slot.

2. The integrated centralized vacuum interconnection system device according to claim 1, wherein the thermal evaporation bearing device comprises a ceramic crucible, a heating resistance wire is coated on the outside of the ceramic crucible, the bottom of the ceramic crucible is connected with a bearing base I, the heating resistance wire is connected with an electrode I, and the electrode I is connected with an insulating ceramic block I arranged on one side of the bearing base I.

3. The integrated centralized vacuum interconnection system device according to claim 1, wherein the electron beam evaporation bearing device includes a metal crucible, a tungsten wire is arranged in the outer center of the metal crucible, the bottom of the metal crucible is connected with the ceramic base set at the center of the bearing base II, the side of the bearing base II is provided with an insulating ceramic block II, an electrode II is arranged on the insulating ceramic block II, the electrode II is connected to a tungsten wire fixation sheet by a connecting wire, the tungsten wire fixation sheet and the connecting wire are connected with the tungsten wire, a ceramic gasket is arranged between the tungsten wire pressing sheet and a fixation nut, the metal crucible is connected with high voltage wiring, the high voltage wiring is connected with the metal crucible and the electrode II, and the outer side of the high voltage wiring is provided with a shielding shell.

4. The integrated centralized vacuum interconnection system device according to claim 1, wherein the probe device includes a bearing base III, and the bearing base III is connected with a holed ceramic, and the holed ceramic is connected with an electrode probe.
